(19) United States
(12) Patent Application Publication
(10) Pub. No.: US 2025/0266369 A1
(43) Pub. Date: Aug. 21, 2025

(54) UNIQUE DIE PATTERNING FOR DIE ATTACH REFERENCING

(71) Applicant: Micron Technology, Inc., Boise, ID (US)

(72) Inventors: Xuanwei Ong, Singapore (SG); Wei Chang Wong, Singapore (SG); Reyhan Wisesa Natanael, Singapore (SG); Xinyun Chen, Singapore (SG); Cheong Kuan Lim, Singapore (SG)

(21) Appl. No.: 19/045,191

(22) Filed: Feb. 4, 2025

Related U.S. Application Data
(60) Provisional application No. 63/556,337, filed on Feb. 21, 2024.

(51) Int. Cl. H01L 23/544; H01L 21/67; H01L 21/68

(52) U.S. Cl. CPC H01L 23/544; H01L 21/67259; H01L 21/67282; H01L 21/681; H01L 2223/54426

(57) ABSTRACT

Systems, devices, and methods for providing unique die patterning are provided herein. A wafer substrate can include a plurality of individual semiconductor dies and a plurality of incomplete dies arranged along an edge of the wafer substrate. Each of the individual semiconductor dies and each of the incomplete dies can include a bond pad array. Each of a subset of the incomplete dies can also include a marking that may be identical or generally similar to the bond pad array. The subset of the incomplete dies, each of which includes both the bond pad array and the marking, can serve as target sites for a die attach machine during an auto-referencing process. In some embodiments, the bond pad arrays and the markings on the subset of the incomplete dies are formed via a photolithography patterning process using the same reticle.

### CROSS-REFERENCE TO RELATED APPLICATION(S)

The present application claims priority to U.S. Provisional Patent Application No. 63/556,337, filed Feb. 21, 2024, the disclosure of which is incorporated herein by reference in its entirety.

### TECHNICAL FIELD

The present disclosure generally relates to semiconductor device assemblies, and more particularly relates to unique die patterning for die attach referencing.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIGS. 1A and 1B are isometric views of a wafer substrate going through a manufacturing process to separate individual semiconductor dies in accordance with embodiments of the present technology.

FIG. 2 is a plan view of a wafer substrate overlaid with a wafer map in accordance with embodiments of the present technology.

FIGS. 3A and 3B are enlarged plan view of an individual semiconductor die and a marked incomplete die, respectively, in accordance with embodiments of the present technology.

FIGS. 4A-4C illustrate cross-sectional views of an incomplete die undergoing a photolithography patterning process to form a bond pad array and a marking in accordance with embodiments of the present technology.

FIG. 5 is a flowchart illustrating a method for patterning a wafer substrate in accordance with embodiments of the present technology.

FIG. 6 is a flowchart illustrating a method for patterning a wafer substrate in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

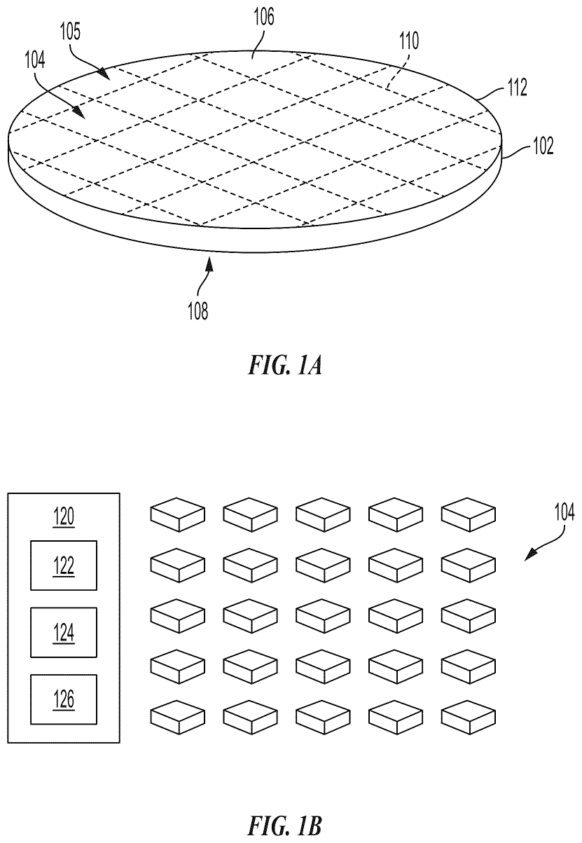

Proper packaging of semiconductor device assemblies involves a particular die, among multiple dies included in a wafer substrate, being selected, transferred, and bonded (e.g., onto another substrate). Conventional die attach processes may designate a subset of the live, functional dies in the wafer as auto-referencing target dies to help determine the relative position of the particular die. However, using live dies as the auto-referencing target dies can introduce several problems attributable to, for example, the relatively small size of the dies and the fact that live dies may be difficult to distinguish from one another. This can lead to incorrect selection failures, which are expected to become increasingly more common as the size of dies decrease as technology advances. It can also be difficult, if not impossible, for such failures to be visually spotted by human observers, since the designated auto-referencing target dies would be virtually indistinguishable to the human eye from other ones of the individual semiconductor dies. Moreover, such failures may be detected too late in the manufacturing and packaging process. To address this problem and others, embodiments of the present technology provide unique die patterning, as illustrated in FIGS. 1A-6.

FIGS. 1A and 1B are isometric views of a wafer substrate 102 going through a manufacturing process to separate individual semiconductor dies 104 (collectively referred to as “individual semiconductor dies” or “the dies,” or independently identified as “each individual semiconductor die,” or “semiconductor die portions” if the dies 104 have not been separated yet). FIG. 1A is an isometric view of the wafer substrate 102 before the wafer substrate 102 has been cut (e.g., singulated) along scribe lines 110. As illustrated, the wafer substrate 102 includes a first surface 106, a second surface 108 opposite the first surface, and active semiconductor components at or proximate the second surface 108. Because the illustrated wafer substrate 102 is a disc (e.g., generally cylindrical) and each of the dies has a generally rectangular shape, the scribe lines 110 separate the wafer substrate 102 into the individual semiconductor dies 104 (or individual semiconductor die portions 104), which have fully rectangular (e.g., square) geometries, and incomplete dies 105 (or “incomplete die portions” if the incomplete dies 105 have not been separated), which are arranged along the edge 112 of the wafer substrate 102 and thus do not have fully rectangular geometries (e.g., having a segmented arch shape). FIG. 1B is an isometric view of the individual semiconductor dies 104 that have been singulated. In some embodiments, only the individual semiconductor dies 104 are further processed and/or packaged while the incomplete dies 105 (or incomplete die portions 105) are discarded.

Once the individual semiconductor dies 104 have been singulated, a die attach machine 120 (illustrated schematically in FIG. 1B) can perform a die attach process. The die attach machine 120 can include pick-and-place equipment 122, a vision system 124, and a controller 126. In some embodiments, the pick-and-place equipment 122 comprises a vacuum nozzle, gripper, or other component configured to securely pick up the individual semiconductor dies 104 and actuators configured to move the individual semiconductor dies 104 with precise positioning and alignment (e.g., onto a substrate or package (not shown)). In some embodiments, the vision system 124 comprises an imaging device (e.g., a camera) or other sensor configured to detect the individual semiconductor dies 104 and enable the precise positioning and alignment. In some embodiments, the controller 126 comprises a microcontroller or other processing unit operably coupled to the pick-and-place equipment 122 and the vision system 124. The controller 126 can operate based on, for example, instructions corresponding to an automated die attach process.

In conventional die attach processes, the die attach machine 120 may store a wafer map (e.g., a digital representation of the wafer substrate 102 stored in a memory or on a server) to be matched with the physical wafer substrate 102 as captured by the vision system 124. The matching process (also referred to as the auto-referencing process) can help the controller 126 properly position, orient, and align the die attach machine 120 with the wafer substrate 102, which in turn can help the pick-and-place equipment 122 operate correctly (e.g., pick up the correct individual semiconductor die 104). To assist with the auto-referencing process, in some conventional die attach processes, the controller 126 can designate a subset of the individual semiconductor dies 104 (e.g., two, three, or more) as auto-referencing target dies. The designated auto-referencing target dies, which are also functional dies, can serve as reference points for the vision system 124 to determine the relative positions of the pick-and-place equipment 122 and the individual semiconductor dies 104 to be packaged. The vision system 124 can also use the edge 112 of the wafer substrate 102 (e.g., its curvature) and/or at least some of the incomplete dies 105 as additional reference points to determine the relative positions.

However, using a subset of the individual semiconductor dies 104 as the designated auto-referencing target dies can introduce several problems attributable to, for example, the relatively small size of the individual semiconductor dies 104 and the fact that the designated auto-referencing target dies would be indistinguishable from other ones of the individual semiconductor dies 104. For example, the vision system 124 and the controller 126 may mix-up or otherwise confuse which ones of the individual semiconductor dies 104 are the designated auto-referencing target dies. This can lead to the pick-and-place equipment 122 selecting the incorrect die for packaging. This type of incorrect selection failure is expected to become increasingly more common as the nodes of dies decrease as technology advances. It can also be difficult, if not impossible, for such failures to be visually spotted by human observers, since the designated auto-referencing target dies would be indistinguishable from other ones of the individual semiconductor dies 104. Moreover, such failures may be detected too late in the manufacturing and packaging process, such as during an Assembly Open/Short Test (AOST) when multiple wafer substrates 102 may have been impacted by the errors.

Therefore, there is a need for more reliable methods of ensuring correct wafer auto-referencing without requiring excessive additional resources (e.g., without using additional components or spending significantly more time). Embodiments of the present technology, as discussed further herein, address some of the concerns raised above.

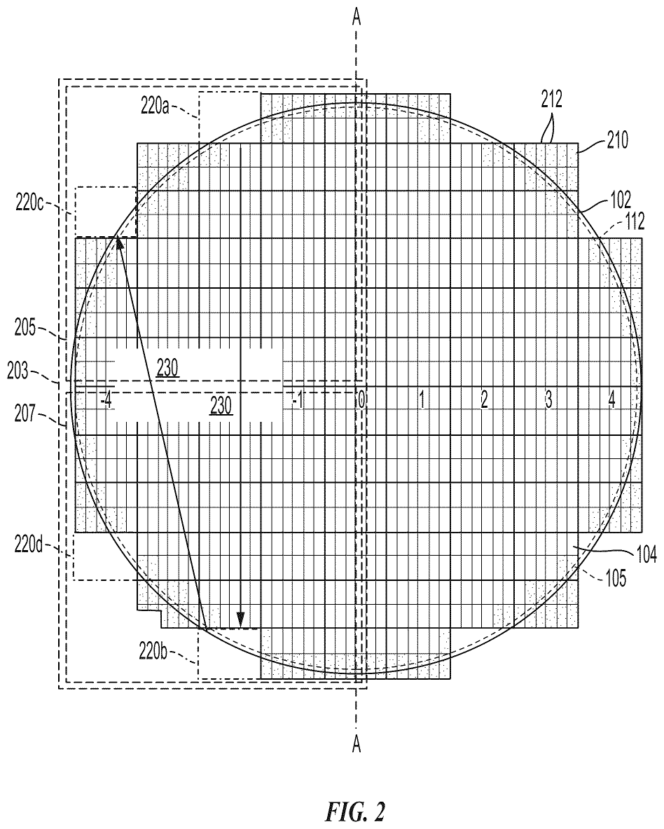

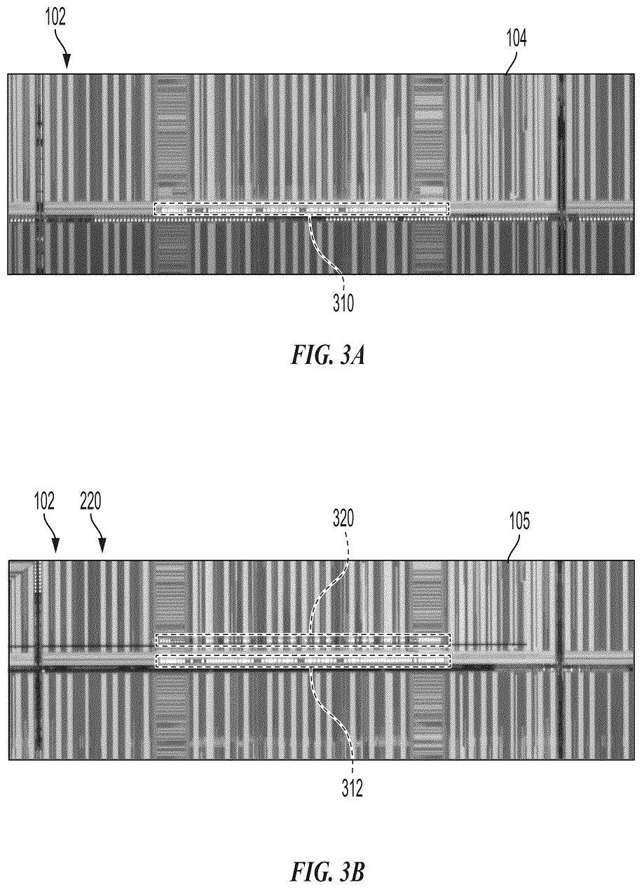

FIG. 2 is a plan view of the wafer substrate 102 overlaid with a wafer map 210. As discussed above, the wafer map 210 can be a digital representation of the wafer substrate 102 stored in a memory or on a server associated with the die attach machine. In some embodiments, the wafer substrate 102 can be an image of the wafer substrate 102 captured by the vision system 124, and the illustrated plan view of FIG. 2 can be what is processed by the controller 126 and/or displayed on a user interface for a human operator to observe. The wafer map 210 can include a plurality of grid spaces 212 corresponding to the individual semiconductor dies 104, the incomplete dies 105, and/or regions beyond the edge 112 of the wafer substrate 102. In some embodiments, the dies have already been singulated prior to the controller 126 processing the illustrated plan view of FIG. 2 such that the grid spaces 212 align with at least some of the singulated dies. In some embodiments, the dies have not been singulated prior to the controller 126 processing the illustrated plan view of FIG. 2 such that the grid spaces 212 merely represent anticipated die locations. The shaded ones of the grid spaces 212 represent those that are at (e.g., overlapping with) or near the edge 112 of the wafer substrate 102. The non-shaded ones of the grid spaces 212 represent those that are farther away from the edge 112 of the wafer substrate 102.

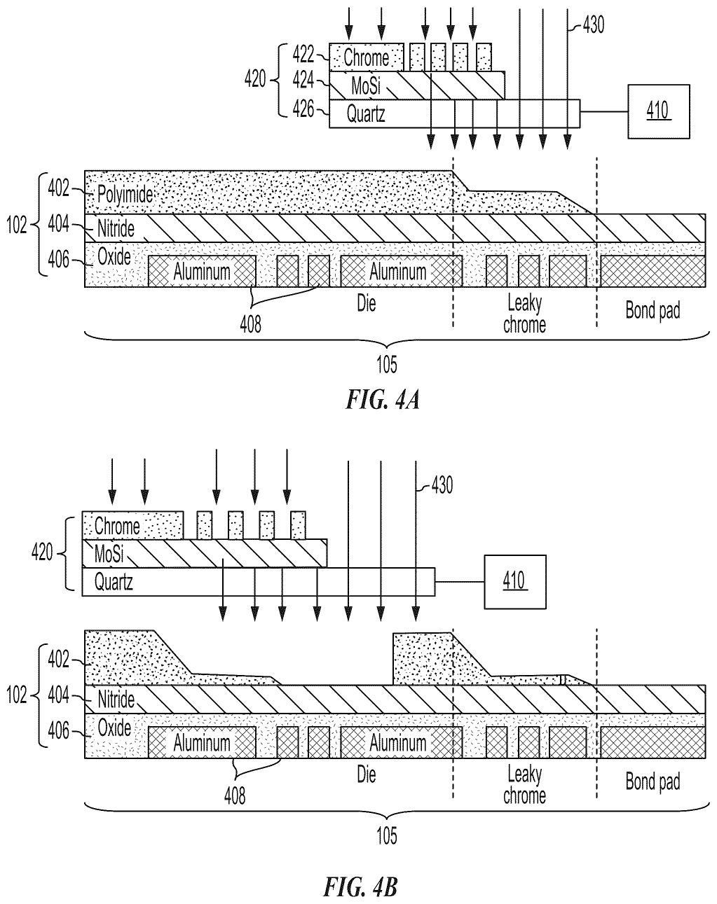

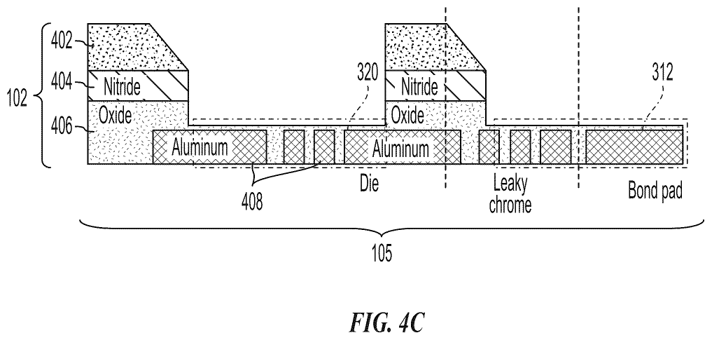

The wafer map 210 can also include a first target site 220a, a second target site 220b, a third target site 220c, and a fourth target site 220d (collectively referred to as “the target sites 220”). In the illustrated embodiment, the target sites 220 are represented as boxes along the edge 112 of the wafer substrate 102 such that a portion of each target site 220 overlaps with the wafer substrate 102, and the remaining portion of each target site 220 extends beyond the edge 112 of the wafer substrate 102. The wafer substrate 102 can include a first half 203 and a second half (not labeled) opposite and adjacent to the first half 203. In some embodiments, the target sites 220 are chosen or determined by the controller 126 such that the target sites 220 are located on the same half of the wafer substrate 102. For example, in the illustrated embodiment, all of the target sites 220 are located on the first half 203 of the wafer substrate 102. This can be to accommodate blading requirements (e.g., of the pick-and-place equipment 122, of the photolithography process illustrated in FIGS. 4A-4C). In some embodiments, the target sites 220 are chosen or determined by the controller 126 such that the target sites 220 are located as far away from one another as possible. In particular, the order of the target sites 220 can be determined such that the maximizing the distance between subsequent target sites 220 is prioritized. For example, the first half 203 can include a first quadrant 205 and a second quadrant 207 opposite and adjacent to the first quadrant 205. In the illustrated embodiment, the first target site 220a is located on the first quadrant 205 of the wafer substrate 102, the second target site 220b is located on the second quadrant 207 of the wafer substrate 102, the third target site 220c is located back on the first quadrant 205 of the wafer substrate 102, the fourth target site 220d is located back on the second quadrant 207 of the wafer substrate 102. As indicated by the arrows 230, moving from one target site 220 to the next involves a longer distance than, for example, moving between adjacent target sites 220. This can be to improve subsequent triangulation or other auto-referencing methods described in further detail herein.

In some embodiments, the controller 126 can identify one or more incomplete dies 105 within each target site 220. As described in further detail below with reference to FIGS. 3B-4C, the identified incomplete dies 105 within the target sites 220 can be marked such that the vision system 124 can subsequently use them for auto-referencing (e.g., locating a specific individual semiconductor die 104 by triangulating between the marked incomplete dies 105). One of ordinary skill in the art will appreciate that the illustrated four target sites 220a-d are merely illustrative, and that the controller 126 can choose fewer (e.g., two, three) or more (e.g., five, six, seven, etc.) target sites 220 at other relative locations on the wafer substrate 102.

FIGS. 3A and 3B are enlarged plan view of an individual semiconductor die 104 and a marked incomplete die 105, respectively. Referring first to FIG. 3A, the illustrated individual semiconductor die 104 of the wafer substrate 102 includes a bond pad array 310. In some embodiments, the bond pad array 310 can be formed via photolithography, patterning, material deposition, etching, coating, and other techniques known in the art. The bond pad array 310 is commonly formed on dies to facilitate the attachment, connection, and electrical interfacing of the die with external components, circuits, or devices using various bonding techniques such as wire bonding, flip-chip bonding, or soldering.

Referring next to FIG. 3B, the illustrated incomplete die 105, located on one of the target sites 220, also includes a bond pad array 312 (e.g., generally identical to the bond pad array 310 formed on the individual semiconductor die 104). The incomplete die 105 further includes a patterning or marking 320 formed proximate to the bond pad array 312. In some embodiments, the marking 320 can be formed on the incomplete die 105 via the same process as the bond pad array 312, as described in further detail below with reference to FIGS. 4A-4C. Moreover, because the incomplete die 105 is not going to be packaged and used, the bond pad array 312 and the marking 320 are both non-functional bond pad arrays, and instead merely serve as visual indicators for the vision system 124 and/or human operators, as described further herein. Each of the individual semiconductor dies 104 can be exclusive of the marking such that only each of the incomplete dies 105 (or a subset thereof) includes the marking 320.

FIGS. 4A-4C illustrate cross-sectional views of the incomplete die 105 undergoing a photolithography patterning process to form the bond pad array 312 and the marking 320. Referring first to FIG. 4A, in the illustrated embodiment, the wafer substrate 102 includes a first layer 402 (e.g., polyimide), a second layer 404 (e.g., nitride) underneath the first layer 402, and a third layer 406 (e.g., oxide) underneath the second layer 404. The first layer 402 can comprises a photoresist material. The third layer 406 can include metal 408 (e.g., aluminum) to be exposed by the photolithography patterning process. In other embodiments, the wafer substrate 102 can include a different number of layers. In addition, a photolithography machine 410 can carry and move a photomask or reticle 420 that can contain the specific pattern or design to be transferred onto the wafer substrate 102 via the photolithography patterning process. In some embodiments, the photolithography machine 410 moves the reticle 420 according to a wafer printing map, which can indicate where the reticle 420 should be located across the wafer substrate 102 throughout the photolithography patterning process. The reticle 420 of the illustrated embodiment includes a first layer 422 (e.g., chrome), a second layer 424 (e.g., molybdenum monosilicide (MoSi)) underneath the first layer 422, and a third layer 426 (e.g., quartz) underneath the second layer 424. In other embodiments, the reticle 420 can include a different number of layers.

FIG. 4A shows the photolithography machine 410 supporting the reticle 420 at a first position over the incomplete die 105, and light rays 430 (e.g., UV light rays emitted by a light source not shown) shining through the reticle 420 and onto the incomplete die 105 to create a first desired pattern. FIG. 4B shows the photolithography machine 410 supporting the reticle 420 at a second position over the incomplete die 105, and light rays 430 shining through the reticle 420 and onto the incomplete die 105 to create a second desired pattern. Because the reticle 420 is often smaller in area than the wafer substrate 102 and expensive to manufacture in a large size, it can be advantageous for the photolithography machine 410 to move the reticle 420 between different position. FIG. 4C shows the incomplete die 105 with the bond pad array 312 and the marking 320 formed by the photolithography patterning process.

It is appreciated that the same or generally similar process can be used to form the bond pad array 310 onto the individual semiconductor die 104. In some embodiments, a first wafer printing map is used to pattern the bond pad arrays 310, 312 onto the multiple individual semiconductor dies 104 and the multiple incomplete dies 105, and a second wafer printing map is used to pattern the markings 320 onto the identified incomplete dies 105 in the target sites 220. The second wafer printing map can include a completely separate and independent set of instructions or pathways for moving the reticle 420 across the wafer substrate 102 compared to the first wafer printing map. This can be advantageous over, for example, simply adding an offset (e.g., corresponding to the distance between the first position of the reticle 420 in FIG. 4A and the second position of the reticle 420 in FIG. 4B) to the photolithography machine 410 and/or the wafer substrate 102 because the photolithography machine 410 and/or the wafer stage (i.e., the device that can move the wafer substrate 102) can have limited and slow movements.

In some embodiments, because the same reticle 420 is used to pattern and form the bond pad array 312 at the first position and the marking 320 at the second position, the resulting first and second desired patterns (i.e., on the bond pad array 312 and the marking 320, respectively), are identical. In some embodiments, a different reticle (or a different portion of the same reticle 420) is used to pattern the bond pad array 312 at the first position and the marking 320 at the second position such that the resulting first and second desired patterns are different. In some embodiments, each of the markings 320 in different target sites 220 can be distinct or unique from one another such that the vision system 124 and human observers can more readily and reliably distinguish between the different target sites 220.

Referring to FIGS. 1A-4C together, once the identified incomplete die 105 in each target site 220 is patterned with the bond pad array 312 and the marking 320, the die attach machine 120 can use the vision system 124 to identify the portions of the wafer substrate 102 corresponding to the target sites 220 of the wafer map 210 for auto-referencing. For example, the vision system 124 can scan dies on or near the edge 112 of the wafer substrate 102, within or near the expected target sites 220 based on the wafer map 210, etc. and search for those incomplete dies 105 with both the bond pad array 312 and the marking 320. In some embodiments, the controller 126 can compare the marking 320 to a lookup table stored in a database to more readily identify which target site 220 the marking 320 corresponds to.

Once the die attach machine 120 identifies the portions of the wafer substrate 102 corresponding to the target sites 220 of the wafer map 210, the die attach machine 120 can proceed with the auto-referencing process. For example, the controller 126 can triangulate between the target sites 220 to ascertain where a specific individual semiconductor die 104 is located on the wafer substrate 102. In another example, the controller 126 can use the first target site 220a as a reference point to locate a specific individual semiconductor die 104 (e.g., 8 mm to the right along an x-axis and 12 mm down along a y-axis from the first target site 220a), then use the second target site 220b, the third target site 220c, and/or the fourth target site 220d as additional reference points to verify that the located individual semiconductor die 104 is the correct one.

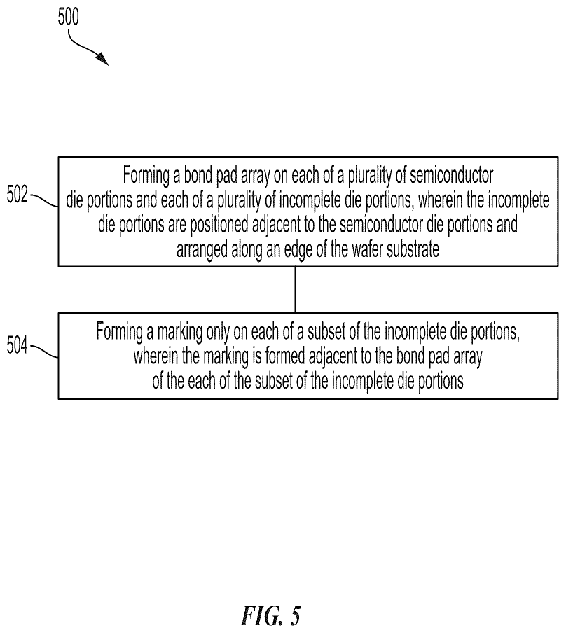

FIG. 5 is a flowchart illustrating a method 500 for patterning a wafer substrate (e.g., the wafer substrate 102). While the method 500 is described below with reference to the embodiments illustrated in FIGS. 1A-4C, one of ordinary skill in the art will appreciate that he method 500 can be performed with other embodiments. The method 500 can include forming a bond pad array (e.g., the bond pad arrays 310, 312) on each of a plurality of semiconductor die portions (e.g., the semiconductor die portions 104) and each of a plurality of incomplete die portions (e.g., the incomplete die portions 105) (process portion 502). In some embodiments, the incomplete die portions are positioned adjacent to the semiconductor die portions and arranged along an edge (e.g., the edge 112) of the wafer substrate. The method 500 can also include forming a marking (e.g., the marking 320) only on each of a subset of the incomplete die portions (e.g., the incomplete die portions 105 corresponding to the target sites 220) (process portion 504). In some embodiments, the marking is formed adjacent to the bond pad array of the each of the subset of the incomplete die portions.

In some embodiments, the bond pad array on each of the semiconductor die portions and each of the incomplete die portions array is formed based on a first wafer printing map, and the marking on each of the subset of the incomplete die portions is formed based on a second wafer printing map distinct from the first wafer printing map. In some embodiments, the bond pad array and the marking of each of the subset of the incomplete die portions comprise a same pattern.

In some embodiments, the bond pad array on each of the semiconductor die portions and each of the incomplete die portions array and the marking on each of the subset of the incomplete die portions are formed by a photolithography patterning process (e.g., as illustrated in FIGS. 4A-4C). In some embodiments, the bond pad array on each of the semiconductor die portions and each of the incomplete die portions array and the marking on each of the subset of the incomplete die portions are formed using a same reticle (e.g., the reticle 420).

In some embodiments, the wafer substrate comprises a first half (e.g., the first half 203) and a second half opposite and adjacent to the first half, and the subset of the incomplete die portions are positioned on the first half. In some embodiments, the first half comprises a first quadrant (e.g., the first quadrant 205) and a second quadrant (e.g., the second quadrant 207) opposite and adjacent to the first quadrant, a first one of the subset of the incomplete die portions (e.g., corresponding to the first target site 220a) is positioned on the first quadrant, and a second one of the subset of the incomplete die portions (e.g., corresponding to the second target site 220b) is positioned on the second quadrant.

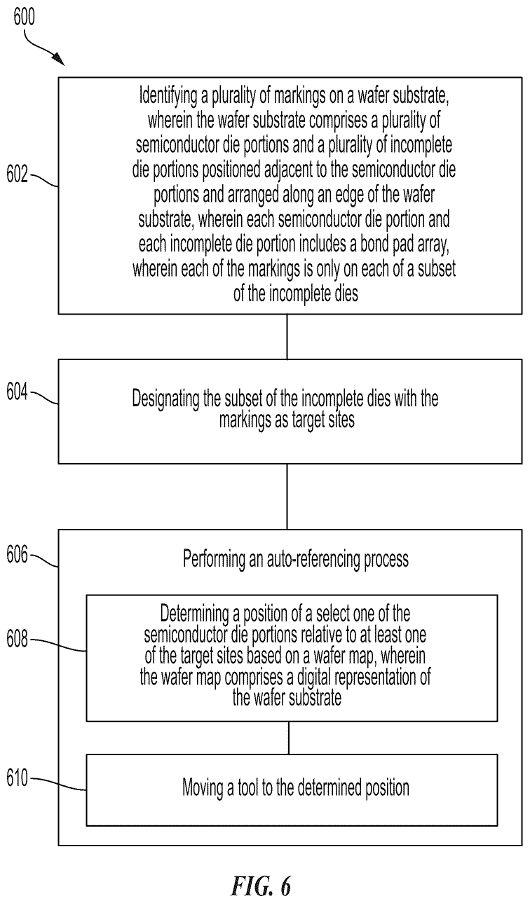

FIG. 6 is a flowchart illustrating a method 600 (e.g., a computer-implemented method) for patterning a wafer substrate (e.g., the wafer substrate 102). While the method 600 is described below with reference to the embodiments illustrated in FIGS. 1A-4C, one of ordinary skill in the art will appreciate that he method 600 can be performed with other embodiments. The method 600 can include identifying (e.g., by a computing system) a plurality of markings (e.g., the markings 320) on a wafer substrate (process portion 602). The wafer substrate 102 can comprise a plurality of semiconductor die portions (e.g., the semiconductor die portions 104) and a plurality of incomplete die portions (e.g., the incomplete die portions 105) positioned adjacent to the semiconductor die portions and arranged along an edge (e.g., the edge 112) of the wafer substrate. Each semiconductor die portion and each incomplete die portion can include a bond pad array (e.g., the bond pad arrays 310, 312), and each of the markings can be only on each of a subset of the incomplete dies.

The method 600 can also include designating (e.g., by the computing system) the subset of the incomplete dies with the markings as target sites (e.g., the target sites 220) (process portion 604). The method 600 can also include performing (e.g., by the computing system) an auto-referencing process (process portion 606). The auto-referencing process can comprise determining (e.g., by the computing system) a position of a select one of the semiconductor die portions relative to at least one of the target sites based on a wafer map (e.g., a digital representation of the wafer substrate) (process portion 608), and moving (e.g., by the computing system) a tool (e.g., the die attach machine 120 or components thereof) to the determined position (process portion 610).

In some embodiments, identifying the markings comprises identifying incomplete dies with both the bond pad array and the marking. In some embodiments, determining the position of the select one of the semiconductor die portions relative to at least one of the target sites comprises determining the position of the select one of the semiconductor die portions relative to a first one of the target sites. The auto-referencing process can further comprise verifying that the tool has moved to the determined position by comparing a position of the tool to a second one of the target sites. In some embodiments, determining the position of the select one of the semiconductor die portions relative to at least one of the target sites comprises triangulating between the target sites.

The flowcharts illustrated in FIGS. 5 and 6 are merely illustrative of the steps or process portions of the methods 500, 600 that can be performed. One of ordinary skill in the art will appreciate that the methods 500, 600 can each include fewer, additional, or alternative process portions.

Referring to FIGS. 1A-6 together, the die patterning and identification processes in accordance with embodiments of the present technology can significantly reduce the risk of incorrect selection failure by a die attach machine 120. Reducing the risk of such failures is becoming increasingly important as the nodes of dies are decreasing as technology advances. Also, compared to conventional processes in which live dies are used as references, the processes disclosed herein can also assist human observers (e.g., production staff) in detecting errors at an earlier stage, such as by providing visual indicators (e.g., the markings 320) that help the human observers determine whether the die attach machine has selected the correct portion of the wafer substrate 102 as the reference point or target site 220. In addition, the process of forming the markings 320 has minimal impact to the overall fabrication process cycle time and cost, and can be scaled to new tech nodes.

Moreover, the patterning processes described herein are not limited to enhancing the accuracy of die attach machines. One of ordinary skill in the art will appreciate that the inclusion of optically recognizable features with minimal additional resources has various applications within the field of semiconductor assembly manufacturing, packaging, and in other fields.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A wafer substrate, comprising:
a plurality of semiconductor die portions, wherein each semiconductor die portion includes a bond pad array; and
a plurality of incomplete die portions positioned adjacent to the semiconductor die portions and arranged along an edge of the wafer substrate, wherein each incomplete die portion includes a bond pad array,
wherein each of a subset of the incomplete die portions includes a marking positioned adjacent to the bond pad array of the each of the subset of the incomplete die portions, and
wherein each of the plurality of semiconductor die portions is exclusive of the marking.

2. The wafer substrate of claim 1, wherein the bond pad array and the marking of each of the subset of the incomplete die portions comprise a same pattern.

3. The wafer substrate of claim 1, wherein the bond pad array and the marking of each of the subset of the incomplete die portions comprise different patterns.

4. The wafer substrate of claim 1, wherein the wafer substrate comprises a disc, wherein each semiconductor die portion comprises a rectangular shape, and wherein each incomplete die portion comprises a segmented arch shape.

5. The wafer substrate of claim 1, wherein each of the bond pad arrays and the markings is formed by a photolithography patterning process.

6. The wafer substrate of claim 5, wherein the bond pad array and the marking of each of the subset of the incomplete die portions are formed using a same reticle.

7. The wafer substrate of claim 1, wherein the subset of the incomplete die portions includes three of the incomplete die portions.

8. The wafer substrate of claim 1, wherein the wafer substrate comprises a first half and a second half opposite and adjacent to the first half, and wherein the subset of the incomplete die portions are positioned on the first half.

9. The wafer substrate of claim 8, wherein the first half comprises a first quadrant and a second quadrant opposite and adjacent to the first quadrant, wherein a first one of the subset of the incomplete die portions is positioned on the first quadrant, and wherein a second one of the subset of the incomplete die portions is positioned on the second quadrant.

10. A method for patterning a wafer substrate, the method comprising:
forming a bond pad array on each of a plurality of semiconductor die portions and each of a plurality of incomplete die portions, wherein the incomplete die portions are positioned adjacent to the semiconductor die portions and arranged along an edge of the wafer substrate; and
forming a marking only on each of a subset of the incomplete die portions, wherein the marking is formed adjacent to the bond pad array of the each of the subset of the incomplete die portions.

11. The method of claim 10, wherein the bond pad array on each of the semiconductor die portions and each of the incomplete die portions array is formed based on a first wafer printing map, and the marking on each of the subset of the incomplete die portions is formed based on a second wafer printing map distinct from the first wafer printing map.

12. The method of claim 10, wherein the bond pad array on each of the semiconductor die portions and each of the incomplete die portions array and the marking on each of the subset of the incomplete die portions are formed by a photolithography patterning process.

13. The method of claim 11, wherein the bond pad array on each of the semiconductor die portions and each of the incomplete die portions array and the marking on each of the subset of the incomplete die portions are formed using a same reticle.

14. The method of claim 10, wherein the wafer substrate comprises a first half and a second half opposite and adjacent to the first half, and wherein the subset of the incomplete die portions are positioned on the first half.

15. The method of claim 14, wherein the first half comprises a first quadrant and a second quadrant opposite and adjacent to the first quadrant, wherein a first one of the subset of the incomplete die portions is positioned on the first quadrant, and wherein a second one of the subset of the incomplete die portions is positioned on the second quadrant.

16. The method of claim 10, wherein the bond pad array and the marking of each of the subset of the incomplete die portions comprise a same pattern.

17. A computer-implemented method for positioning a tool relative to a wafer substrate, the computer-implemented method comprising:
identifying, by a computing system, a plurality of markings on a wafer substrate, wherein the wafer substrate comprises a plurality of semiconductor die portions and a plurality of incomplete die portions positioned adjacent to the semiconductor die portions and arranged along an edge of the wafer substrate, wherein each semiconductor die portion and each incomplete die portion includes a bond pad array, wherein each of the markings is only on each of a subset of the incomplete dies;
designating, by the computing system, the subset of the incomplete dies with the markings as target sites; and
performing, by the computing system, an auto-referencing process comprising:
determining, by the computing system, a position of a select one of the semiconductor die portions relative to at least one of the target sites based on a wafer map, wherein the wafer map comprises a digital representation of the wafer substrate; and
moving, by the computing system, a tool to the determined position.

18. The computer-implemented method of claim 17, wherein identifying the markings comprises identifying incomplete dies with both the bond pad array and the marking.

19. The computer-implemented method of claim 17, wherein determining the position of the select one of the semiconductor die portions relative to at least one of the target sites comprises determining the position of the select one of the semiconductor die portions relative to a first one of the target sites, and wherein the auto-referencing process further comprises verifying that the tool has moved to the determined position by comparing a position of the tool to a second one of the target sites.

20. The computer-implemented method of claim 17, wherein determining the position of the select one of the semiconductor die portions relative to at least one of the target sites comprises triangulating between the target sites.
